(19) United States
(12) Patent Application Publication
(10) Pub. No.: US 2008/0149973 A1
(43) Pub. Date: Jun. 26, 2008

(54) SEMICONDUCTOR DEVICE AND METHOD FOR MANUFACTURING THE SAME

(76) Inventor: Jea Hee Kim, Yeoju-gun (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/961,605

(22) Filed: Dec. 20, 2007

(30) Foreign Application Priority Data
Dec. 22, 2006 (KR) 10-2006-0132349

(51) Int. Cl. H01L 31/103; H01L 31/18

(52) U.S. Cl. 257/290; 438/59; 257/E31.057

(57) ABSTRACT

A method for manufacturing a semiconductor device is provided. The method includes: forming a gate insulating layer on a semiconductor substrate having an isolation layer formed therein, forming a gate electrode on the gate insulating, implanting low-concentration impurity ions on the semiconductor substrate at a first side of the gate electrode to form a lightly doped drain (LDD) region, forming a low-concentration impurity region on the semiconductor substrate at a second side of the gate electrode, implanting impurities into the low-concentration impurity region to form a photodiode, and forming micro pits on a top surface of the photodiode using a wet etching process.

The present application claims the benefit of priority under 35 U.S.C. § 119 to Korean Patent Application No. 10-2006-0132349, filed on Dec. 22, 2006, the entire contents of which are incorporated herein by reference.

### BACKGROUND

The present invention relates to a semiconductor device and a method for manufacturing the same.

Image sensors, which may be implemented as semiconductor devices, convert optical images into electrical signals. In general, image sensors may be classified as a charge coupled device (CCD) type or a complementary metal oxide silicon (CMOS) type.

The CMOS type image sensor may include a photodiode that senses light, and a CMOS logic circuit that converts the sensed light into electrical signals and converts the electrical signals into data. In order to increase the light sensitivity of the CMOS type image sensor, an effort has been made to increase a ratio (or “fill factor”) of an area of the photodiode to an entire area of the image sensor.

The photodiode serves to receive external light, to convert the received external light into an electrical form, and to preserve the result. Thus, the performance of the photodiode may be determined based on its efficiency of external light reception, its efficiency of photoelectric conversion, and its capacity of electricity preservation.

Further, a micro-lens structure may be formed on the photodiode structure, so as to increase a light collection rate of the photodiode.

With the advances of semiconductor technologies, the design rules have become strict, and thus a minimum line width is reduced. For this reason, the photodiode is reduced in size, and a quantity of electrons created by the photodiode in response to incident light is reduced.

### SUMMARY

In light of the above, there is provided a semiconductor device and a method for manufacturing the same, in which micro pits are formed on a top surface of a photodiode. The micro pits formed on the photodiode may prevent light incident through a micro lens formed on the photodiode from being reflected from the photodiode, thereby increasing an electron creation rate in response to the incident light.

In one embodiment consistent with the present invention, a method for manufacturing a semiconductor device is provided. The method includes: forming a gate insulating layer on a semiconductor substrate having an isolation layer formed therein; and forming a gate electrode on the gate insulating layer a semiconductor substrate having an isolation layer; implanting low-concentration impurity ions on the semiconductor substrate at a first side of the gate electrode to form a lightly doped drain (LDD) region; forming a low-concentration impurity region on the semiconductor substrate at a second side of the gate electrode in order to form a photodiode; implanting impurities into the low-concentration impurity region to form the a photodiode; and forming micro pits in on a top surface of the photodiode using a wet etching process.

In another embodiment consistent with the present invention, a semiconductor device is provided. The semiconductor device includes: a semiconductor substrate having an isolation layer formed therein; a gate insulating layer formed on the semiconductor substrate; a gate electrode formed on the gate insulating layer; a lightly doped drain (LDD) region formed on the semiconductor substrate at a first side of the gate electrode; a low-concentration impurity region formed on the semiconductor substrate at a second side of the gate electrode; a photodiode formed in the low-concentration impurity region; and micro pits formed on a top surface of the photodiode.

### BRIEF DESCRIPTION OF THE DRAWINGS

FIGS. 1 through 6 are sectional views illustrating a method for manufacturing a semiconductor device consistent with the present invention.

### DETAILED DESCRIPTION

Hereinafter, a semiconductor device and a method for manufacturing the same consistent with the present invention will be described in detail with reference to the accompanying drawings.

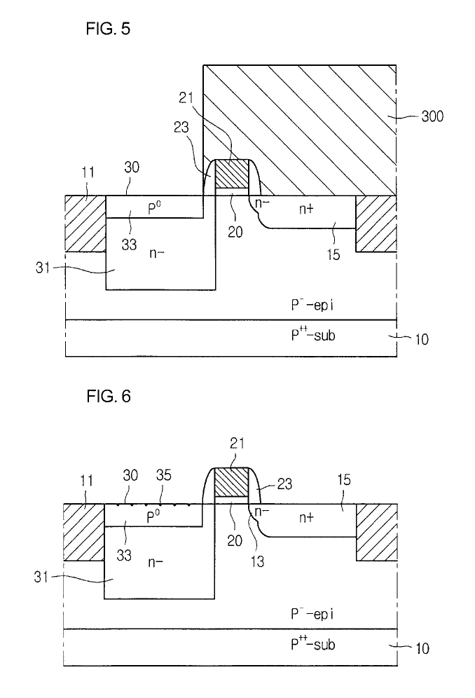

FIG. 6 is a sectional view illustrating a semiconductor device consistent with the present invention.

As shown in FIG. 6, the semiconductor device may include a gate insulating layer 20 and a gate electrode 21 formed on a semiconductor substrate 10 having an isolation layer 11 formed therein, a lightly doped drain (LDD) region 13 formed on one side of gate electrode 21 by implantation of low-concentration impurity ions, a low-concentration impurity region 31 formed on the other side of gate electrode 21, a photodiode 30 formed by implanting impurities into low-concentration impurity region 31, and micro pits 35 formed on a top surface of photodiode 30.

Photodiode 30 may include a p-type impurity region p0 formed on an n-type impurity region (n⁻) 31.

Each micro pit 35 may have a width between about 1 nm and about 10 nm, and a depth between about 10 nm and about 50 nm. Micro pits 35 may prevent light incident onto photodiode 30 from being reflected, so as to improve the light sensitivity of photodiode 30.

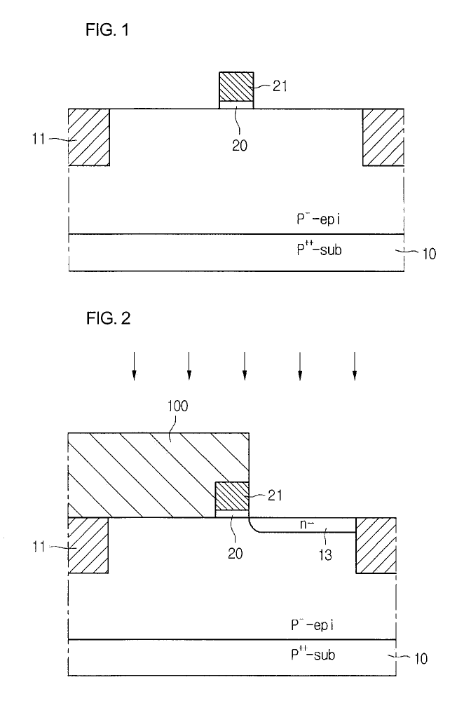

FIGS. 1 through 6 are sectional views illustrating a method for manufacturing a semiconductor device consistent with the present invention.

Referring to FIG. 1, a gate insulating layer 20 and a gate electrode 21 are sequentially formed on a semiconductor substrate 10, in which an isolation layer 11 has been formed. Semiconductor substrate 10 may comprise a heavily doped p-type semiconductor substrate p⁺⁺-sub. Further, a p-type epitaxial layer p⁻-epi having a concentration lower than that of p-type semiconductor substrate p⁺⁺-sub may be formed in advance on p-type semiconductor substrate p⁺⁺-sub. This low-concentration epitaxial layer p⁻-epi not only increases the depth of a depletion layer of the photodiode, but also prevents cross talk between unit pixels formed on semiconductor substrate 10. In one embodiment, isolation layer 11 may be formed in p-type epitaxial layer p⁻-epi using, for example, a shallow trench isolation (STI) process.

Referring to FIG. 2, a photoresist layer is formed on an entire surface of semiconductor substrate 10, and then a photoresist pattern 100 is formed using a photolithography process. Photoresist pattern 100 defines a low-concentration impurity region, in which an LDD region 13 may be formed at one side of gate electrode 21. At this time, photoresist pattern 100 is formed so as not to expose gate electrode 21.

Low-concentration impurity ions may be implanted into semiconductor substrate 10, thereby forming low-concentration impurity region (LDD n⁻) 13. For example, the low-concentration impurity ions may include n-type impurity ions.

After low-concentration impurity region (LDD n⁻) 13 for an LDD structure is formed in semiconductor substrate 10, photoresist pattern 100 is removed.

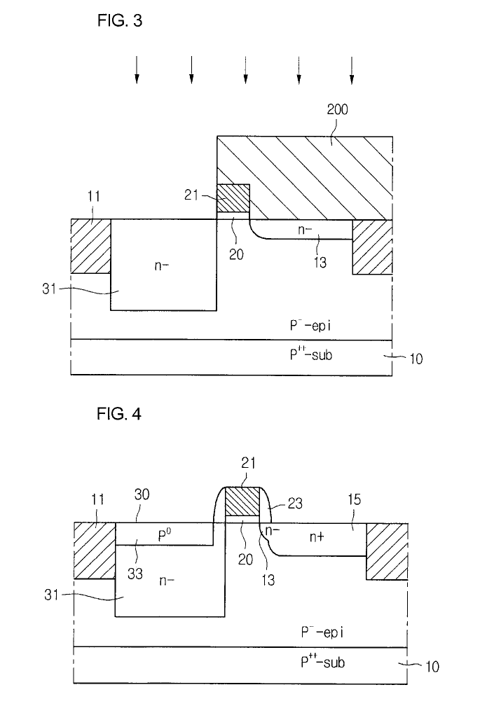

Referring to FIG. 3, a photoresist layer is formed on an entire surface of semiconductor substrate 10, and then a photoresist pattern 200 is formed using a photolithography process. Photoresist pattern 200 does not expose low-concentration impurity region 13 and gate electrode 21.

A low-concentration impurity region (n⁻) 31 for forming the photodiode is formed using photoresist pattern 200 as an ion implantation mask, and then photoresist pattern 200 is removed.

Referring to FIG. 4, spacers 23 are formed on sidewalls of gate electrode 21, and then a p-type impurity region (p0) 33 is formed on n-type impurity region (n⁻) 31. The process for forming photodiode 30 is completed.

Photodiode 30 thus formed may comprise n-type impurity region (n⁻) 31 formed in p-type semiconductor substrate 10, and p-type impurity region (p0) 33 formed on n-type impurity region (n⁻) 31. Thus, photodiode 30 has a p-n-p structure together with p-type epitaxial layer p⁻-epi.

When photodiode 30 is completely formed, high-concentration impurity ions may be selectively implanted in low-concentration impurity region 13, and then a heat treatment process may be performed. A high-concentration impurity region (n⁺) 15 may thus be formed in the drain region of the semiconductor device.

Referring to FIG. 5, a photoresist layer is formed on semiconductor substrate 10, and then a photoresist pattern 300 is formed using a photolithography process. Photoresist pattern 300 exposes photodiode 30.

When photodiode 30 is exposed by photoresist pattern 300, micro pits 35 are formed on a top surface of photodiode 30 using a wet etching process.

In one embodiment, an etchant may be used to form micro pits 35 on the top surface of photodiode 30 according to a crystal structure of photodiode 30. For example, the etchant may comprise a SECCO etchant, and the wet etching process may be performed for a time of about 10 to 30 seconds at a temperature of about 45 to 60° C.

The SECCO etchant may include potassium hydroxide (KOH), sodium hydroxide (NaOH), and a mixture of other compounds.

As illustrated in FIG. 6, the top surface of photodiode 30 includes micro pits 35 having a width of about 1 nm to 10 nm and a depth of about 10 nm to 50 nm.

When micro pits 35 are formed on the top surface of photodiode 30 using the etchant, the top surface of photodiode 30 has a hexagonal crystal structure.

Further, because each micro pit 35 has a groove-type cross section, light incident onto photodiode 30 may pass through photodiode 30 without reflection, thereby effectively creating electrons.

In the method for manufacturing a semiconductor device consistent with the present invention, micro pits 35 are formed on the top surface of photodiode 30, which is a light-collecting region of photodiode 30, so as to prevent reflection of light incident onto photodiode 30.

Further, photodiode 30 having micro pits 35 may increase an electron conversion rate of light passing through photodiode 30.

Although embodiments consistent with the present invention have been described in detail, it should be understood that numerous other modifications and variations can be devised by those skilled in the art. More particularly, various variations and modifications are possible in the component parts and/or arrangements of the subject combination arrangement. In addition to variations and modifications in the component parts and/or arrangements, alternative uses will also be apparent to those skilled in the art.

What is claimed is:

1. A method for manufacturing a semiconductor device, comprising:
forming a gate insulating layer on a semiconductor substrate having an isolation layer formed therein;
forming a gate electrode on the gate insulating layer;
implanting low-concentration impurity ions on the semiconductor substrate at a first side of the gate electrode to form a lightly doped drain (LDD) region;
forming a low-concentration impurity region on the semiconductor substrate at a second side of the gate electrode;
implanting impurities into the low-concentration impurity region to form a photodiode; and
forming micro pits on a top surface of the photodiode using a wet etching process.

2. The method as recited in claim 1, further comprising forming a photoresist pattern exposing the top surface of the photodiode to form the micro pits on the top surface of the photodiode.

3. The method as recited in claim 1, wherein the wet etching process uses a SECCO etchant.

4. The method as recited in claim 1, wherein each micro pit has a width of about 1 nm to about 10 nm and a depth of about 10 nm to 50 nm.

5. The method as recited in claim 1, wherein forming the micro pits comprises performing the wet etching process for a time of about 10 to 30 seconds at a temperature of about 45 to 60° C.

6. A semiconductor device comprising:
a semiconductor substrate having an isolation layer formed therein;
a gate insulating layer formed on the semiconductor substrate;
a gate electrode formed on the gate insulating layer;
a lightly doped drain (LDD) region formed on the semiconductor substrate at a first side of the gate electrode;
a low-concentration impurity region formed on the semiconductor substrate at a second side of the gate electrode;
a photodiode formed in the low-concentration impurity region; and
micro pits formed on a top surface of the photodiode.

7. The semiconductor device as recited in claim 6, wherein each micro pit has a width of about 1 nm to about 10 nm and a depth of about 10 nm to 50 nm.

8. The semiconductor device as recited in claim 6, wherein the photodiode includes an n-type impurity region and a p-type impurity region.
